(19) United States
(12) Patent Application Publication
(10) Pub. No.: US 2026/0096445 A1
(43) Pub. Date: Apr. 2, 2026

(54) SEMICONDUCTOR DEVICES

(71) Applicant: Samsung Electronics Co., Ltd., Suwon-si (KR)

(72) Inventors: Seongmin Son, Suwon-si (KR); Seokho Kim, Suwon-si (KR); Tae Young Kim, Suwon-si (KR); Kyu-Ha Lee, Suwon-si (KR); Ho-Jin Lee, Suwon-si (KR); Dong-Chan Lim, Suwon-si (KR); Joo Hee Jang, Suwon-si (KR)

(21) Appl. No.: 19/174,082

(22) Filed: Apr. 9, 2025

(30) Foreign Application Priority Data
Sep. 27, 2024 (KR) 10-2024-0132150

(51) Int. Cl. H01L 23/544; H01L 23/00; H01L 25/065; H01L 25/16; H01L 25/18; H10B 80/00; H10D 80/30

(52) U.S. Cl. CPC H10W 46/00; H10B 80/00; H10D 80/30; H10W 46/301; H10W 72/90; H10W 72/922; H10W 72/934; H10W 80/163; H10W 80/312; H10W 80/327; H10W 90/00; H10W 90/792

(57) ABSTRACT

A semiconductor device includes a substrate that comprises a first region and a second region; a first wiring structure on the first region of the substrate, wherein the first wiring structure comprises a lower bonding pad; a second wiring structure on the first wiring structure, wherein the second wiring structure comprises an upper bonding pad that contacts the lower bonding pad; a lower alignment pattern on the second region of the substrate, wherein the lower alignment pattern is spaced apart from the lower bonding pad; and an upper alignment pattern on the second region of the substrate, wherein the upper alignment pattern is spaced apart from the upper bonding pad, wherein the lower alignment pattern comprises sub-lower alignment patterns, and wherein the upper alignment pattern comprises sub-upper alignment patterns.

### CROSS-REFERENCE TO RELATED APPLICATION

This application claims priority to Korean Patent Application No. 10-2024-0132150, filed in the Korean Intellectual Property Office on Sep. 27, 2024, the entire contents of which are hereby incorporated by reference.

### BACKGROUND

The present disclosure relates to semiconductor devices.

There is a need for semiconductor memory devices capable of storing high-capacity data in electronic systems that require data storage. Accordingly, ways to increase the data storage capacity of the semiconductor memory devices are being studied. For example, a semiconductor device has been proposed as one of the methods to increase the data storage capacity of the semiconductor device, which includes three-dimensional arrangement of memory cells instead of two-dimensional arrangement of memory cells.

### SUMMARY

The present disclosure may provide semiconductor devices with improved electrical characteristics and reliability The present disclosure may solve one or more problems described above and/or other problems not explicitly described herein.

According to some embodiments, a width of the lower alignment pattern in one direction is 10% to 300% of a width of the lower bonding pad in the one direction, and the upper surface of the lower bonding pad and the upper surface of the lower alignment pattern may be disposed at the same or similar level. As a result, the first wafer and the second wafer may be stably coupled to each other, and electrical characteristics and reliability of the semiconductor device can be improved.

According to some embodiments, a width of the upper alignment pattern in one direction is 10% to 300% of a width of the upper bonding pad in the one direction, and the lower surface of the upper bonding pad and the lower surface of the upper alignment pattern can be disposed at the same or similar level. As a result, the first wafer and the second wafer may be stably coupled to each other, and electrical characteristics and reliability of the semiconductor device can be improved.

According to some embodiments of the present disclosure, a semiconductor device may include a substrate that comprises a first region and a second region; a first wiring structure on the first region of the substrate, wherein the first wiring structure comprises a lower bonding pad; a second wiring structure on the first wiring structure, wherein the second wiring structure comprises an upper bonding pad that is in contact with the lower bonding pad; a lower alignment pattern on the second region of the substrate, wherein the lower alignment pattern is spaced apart from the lower bonding pad in a horizontal direction that is parallel with an upper surface and/or a lower surface of the substrate; and an upper alignment pattern on the second region of the substrate, wherein the upper alignment pattern is spaced apart from the upper bonding pad in the horizontal direction, wherein the lower alignment pattern comprises sub-lower alignment patterns, wherein the upper alignment pattern comprises sub-upper alignment patterns, wherein at least one of the sub-lower alignment patterns has a ring shape, and
wherein at least one of the sub-upper alignment patterns has a ring shape.

According to some embodiments of the present disclosure, a semiconductor device may include a lower interlayer insulating film; a lower bonding pad in the lower interlayer insulating film; a lower alignment pattern in the lower interlayer insulating film, wherein the lower alignment pattern is spaced apart from the lower bonding pad in a horizontal direction that is parallel with an upper surface and/or a lower surface of the lower interlayer insulating film; an upper interlayer insulating film on the lower interlayer insulating film; an upper bonding pad in the upper interlayer insulating film, wherein the upper bonding pad is in contact with the lower bonding pad; and an upper alignment pattern in the upper interlayer insulating film, wherein the upper alignment pattern is spaced apart from the upper bonding pad in the horizontal direction, wherein the lower alignment pattern comprises sub-lower alignment patterns, and wherein a width of at least one of the sub-lower alignment patterns in a direction is 10% to 300% of a width of the lower bonding pad in the direction.

According to some embodiments of the present disclosure, a semiconductor device may include a substrate that comprises a first region and a second region that is adjacent the first region; a peripheral circuit structure on the first region; a cell structure on the peripheral circuit structure; and a lower alignment pattern and an upper alignment pattern on the second region of the substrate, wherein the cell structure comprises: gate electrodes that are stacked on and spaced apart from each other in a first direction that is perpendicular to an upper surface and/or a lower surface of the substrate; a channel structure that extends into the gate electrodes in the first direction; a bit line that is electrically connected to the channel structure; and an upper bonding pad that is electrically connected to the bit line, the peripheral circuit structure comprises: a lower bonding pad that is in contact with the upper bonding pad; and a peripheral circuit element that is electrically connected to the lower bonding pad, wherein the lower alignment pattern comprises sub-lower alignment patterns, wherein a width of at least one of the sub-lower alignment patterns in a second direction is 10% to 300% of a width of the lower bonding pad in the second direction, and wherein the second direction is parallel with the upper surface and/or the lower surface of the substrate.

### BRIEF DESCRIPTION OF THE DRAWINGS

The above and other embodiments and features of the present disclosure will become more apparent by describing in detail example embodiments thereof with reference to the attached drawings, in which:

FIG. 1 is a diagram illustrating a semiconductor substrate on which a semiconductor device is positioned (integrated) according to some embodiments;

FIG. 2 is a cross-sectional view taken along line A-A′ of FIG. 1;

FIG. 3 is an enlarged view provided to explain the region Q1 of FIG. 2;

FIG. 4 is an enlarged view provided to explain the region Q2 of FIG. 2;

FIG. 5 is a plan view illustrating an alignment key of a semiconductor device according to some embodiments;

FIG. 6 is a diagram provided to explain a semiconductor device according to some embodiments;

FIGS. 7 and 8 are diagrams provided to explain the alignment key of the semiconductor device according to some embodiments;

FIG. 9 is a diagram provided to explain the alignment key of the semiconductor device according to some embodiments;

FIG. 10 is a diagram provided to explain an alignment key of a semiconductor device according to some embodiments;

FIG. 11 is a diagram provided to explain an alignment key of a semiconductor device according to some embodiments;

FIGS. 12 and 13 are diagrams provided to explain the alignment key of the semiconductor device according to some embodiments;

FIG. 14 is a diagram provided to explain a semiconductor device according to some embodiments;

FIGS. 15 and 16 are diagrams provided to explain a semiconductor device according to some embodiments;

FIG. 17 is a diagram provided to explain a semiconductor device according to some embodiments;

FIG. 18 is a cross-sectional view taken along line B-B′ of FIG. 17;

FIG. 19 is an example block diagram provided to explain an electronic system according to some embodiments;

FIG. 20 is a perspective view provided as an example to explain an electronic system according to some embodiments;

FIG. 21 is a schematic cross-sectional view taken along line V-V′ of FIG. 20.

### DETAILED DESCRIPTION

Hereinafter, a semiconductor device according to some embodiments of the disclosure will be described in detail with reference to the drawings.

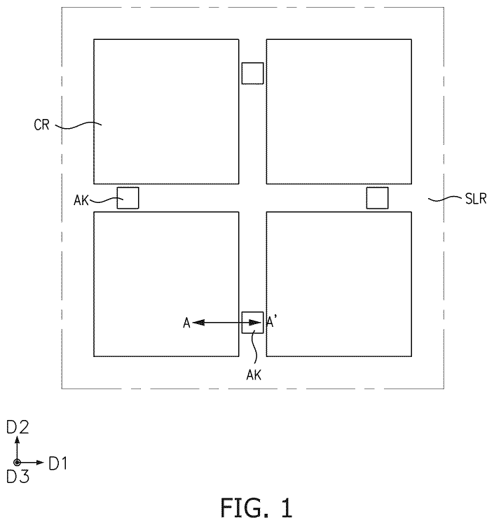

FIG. 1 is a diagram illustrating a semiconductor substrate on which a semiconductor device is positioned (integrated) according to some embodiments.

Referring to FIG. 1, a semiconductor substrate may include a plurality of chip regions CR in which semiconductor chips are formed, and a scribe line region SLR disposed between (adjacent ones of) the plurality of chip regions CR. The chip regions CR may be two-dimensionally arranged in first and second directions D1 and D2 intersecting each other. The first and second directions D1 and D2 may be horizontal directions parallel with an upper surface and/or a lower surface of the semiconductor substrate. In some embodiments, in a plan view, the scribe line region SLR may extend around (each of) the chip regions CR. For example, each chip region CR may be surrounded by the scribe line region SLR. That is, the scribe line region SLR may be disposed between the chip regions CR adjacent to each other in the first direction D1 and between the chip regions CR adjacent to each other in the second direction D2.

An alignment key AK may be disposed in the scribe line region SLR. That is, the alignment key AK may be disposed adjacent (around) the chip region CR. FIG. 1 illustrates that the number of alignment keys AK is four, but embodiments are not limited thereto. For example, the number of alignment keys AK may be less than four or greater than four.

The semiconductor substrate may be a bulk silicon substrate, a silicon-on-insulator (SOI) substrate, a germanium substrate, a germanium-on-insulator (GOI) substrate, a silicon-germanium substrate, or a substrate of an epitaxial thin film obtained by performing selective epitaxial growth (SEG).

According to some embodiments, a semiconductor device including memory cells three-dimensionally arranged in each of the chip regions CR of the semiconductor substrate may be formed.

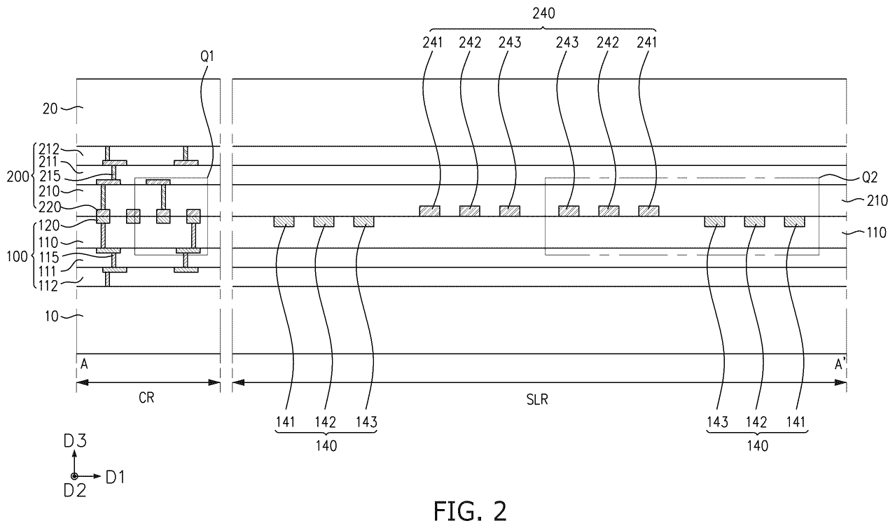

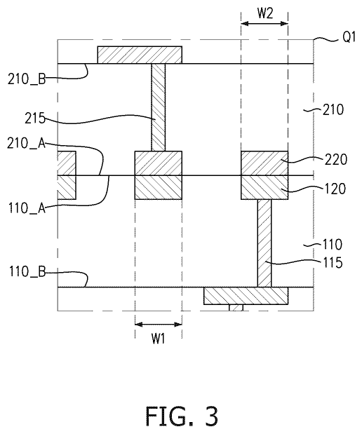

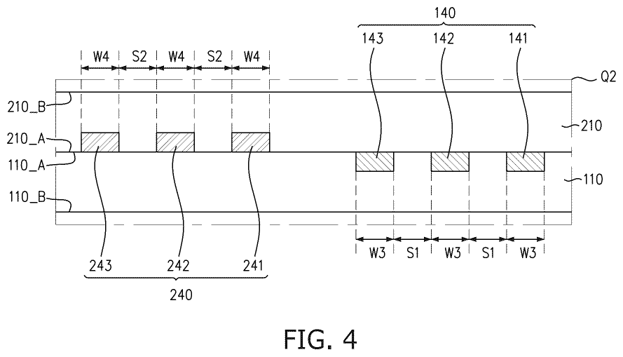

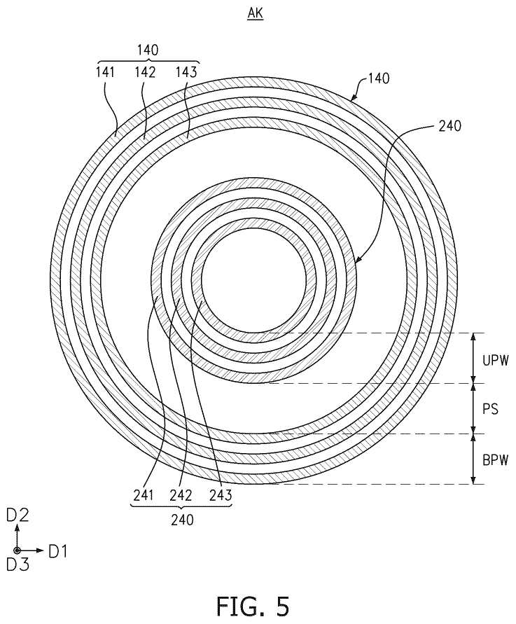

FIG. 2 is a cross-sectional view taken along line A-A′ of FIG. 1. FIG. 3 is an enlarged view provided to explain the region Q1 of FIG. 2. FIG. 4 is an enlarged view provided to explain the region Q2 of FIG. 2. FIG. 5 is a plan view illustrating an alignment key of a semiconductor device according to some embodiments.

Referring to FIGS. 2 to 5, a semiconductor device according to some embodiments may include a chip region CR and a scribe line region SLR. The chip region CR and the scribe line region SLR of the semiconductor device may correspond to the chip region CR and the scribe line region SLR of FIG. 1.

A first wiring structure 100 and a second wiring structure 200 may be disposed on the chip region CR of a first semiconductor chip 10. The first wiring structure 100 may be between the second wiring structure 200 and the first semiconductor chip 10 in a third direction D3 that is perpendicular to the upper and/or the lower surfaces of the substrate. The first wiring structure 100 may include a first lower interlayer insulating film 110, a second lower interlayer insulating film 111, a third lower interlayer insulating film 112, a lower bonding pad 120, and a lower connection wire 115.

The first lower interlayer insulating film 110 may include a first surface 110_A (e.g., an upper surface) and a second surface 110_B (e.g., a lower surface). The first surface 110_A of the first lower interlayer insulating film 110 may be in contact with a first upper interlayer insulating film 210 (which will be described in detail below). The second surface 110_B of the first lower interlayer insulating film 110 may be opposite to the first surface 110_A in the third direction D3. The third direction D3 may be a direction intersecting with the first direction D1 and the second direction D2, respectively.

The lower bonding pad 120 may be disposed on (in) the first lower interlayer insulating film 110. The first lower interlayer insulating film 110 may expose an upper surface of the lower bonding pad 120. For example, the first lower interlayer insulating film 110 may not cover (may not overlap in the third direction D3) the upper surface of the lower bonding pad 120.

The lower bonding pad 120 may be disposed on the first surface 110_A of the first lower interlayer insulating film 110. In some embodiments, the upper surface of the lower bonding pad 120 may be disposed on the same plane as the first surface 110_A of the first lower interlayer insulating film 110. The upper surface of the lower bonding pad 120 may be coplanar with the first surface 110_A of the first lower interlayer insulating film 110. However, embodiments are not limited thereto.

The second lower interlayer insulating film 111 may be disposed under the first lower interlayer insulating film 110. The third lower interlayer insulating film 112 may be disposed under the second lower interlayer insulating film 111. The second lower interlayer insulating film 111 may be between the first lower interlayer insulating film 110 and the third lower interlayer insulating film 112. Each of the first, second, and third lower interlayer insulating films 110, 111, and 112 may include, for example, silicon oxide (SiO), silicon nitride (SiN), silicon oxynitride (SiON), and/or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, and/or a combination thereof. However, embodiments are not limited thereto.

Although it is illustrated that the first lower interlayer insulating film 110 and the second lower interlayer insulating film 111 are in contact with each other, embodiments are not limited thereto. For example, a silicon nitride film may be disposed between the first lower interlayer insulating film 110 and the second lower interlayer insulating film 111 (in the third direction D3). In some embodiments, a silicon nitride film may be disposed between the second lower interlayer insulating film 111 and the third lower interlayer insulating film 112 (in the third direction D3).

The lower connection wire 115 may be disposed in the first, second, and third lower interlayer insulating films 110, 111, and 112. The lower connection wire 115 may be (electrically) connected to the lower bonding pad 120. The lower connection wire 115 may be (electrically) connected to the first semiconductor chip 10. For example, the lower connection wire 115 may (electrically) connect the lower bonding pad 120 to the first semiconductor chip 10.

The second wiring structure 200 may be on the first wiring structure 100. The second wiring structure 200 may include the first upper interlayer insulating film 210, a second upper interlayer insulating film 211, a third upper interlayer insulating film 212, an upper bonding pad 220, and an upper connection wire 215.

The first upper interlayer insulating film 210 may include a first surface 210_A and a second surface 210_B. The first surface 210_A of the first upper interlayer insulating film 210 may be in contact with (the first surface 110_A of) the first lower interlayer insulating film 110. The second surface 210_B of the first upper interlayer insulating film 210 may be opposite to the first surface 210_A in the third direction D3.

The upper bonding pad 220 may be disposed on (in) the first upper interlayer insulating film 210. The first upper interlayer insulating film 210 may expose a lower surface of the upper bonding pad 220. For example, the first upper interlayer insulating film 210 may not cover (or overlap in the third direction D3) the lower surface of the upper bonding pad 220.

The upper bonding pad 220 may be disposed on the first surface 210_A of the first upper interlayer insulating film 210. In some embodiments, the lower surface of the upper bonding pad 220 may be disposed on the same plane as the first surface 210_A of the first upper interlayer insulating film 210. For example, the lower surface of the upper bonding pad 220 may be coplanar with the first surface 210_A. However, embodiments are not limited thereto.

The second upper interlayer insulating film 211 may be disposed above (on) the first upper interlayer insulating film 210. The third upper interlayer insulating film 212 may be disposed above (on) the second upper interlayer insulating film 211. The second upper interlayer insulating film 211 may be between the first upper interlayer insulating film 210 and the third upper interlayer insulating film 212 in the third direction D3. Description of each material of the first, second, and third upper interlayer insulating films 210, 211, and 212 may be the same as (or substantially similar to) the description of the first, second, and third lower interlayer insulating films 110, 111, and 112.

Although it is illustrated that the first upper interlayer insulating film 210 and the second upper interlayer insulating film 211 are in contact with each other, embodiments are not limited thereto. For example, a silicon nitride film may be disposed between the first upper interlayer insulating film 210 and the second upper interlayer insulating film 211 (in the third direction D3). In some embodiments, a silicon nitride film may be disposed between the second upper interlayer insulating film 211 and the third upper interlayer insulating film 212 (in the third direction D3).

The upper connection wire 215 may be disposed in the first, second, and third upper interlayer insulating films 210, 211, and 212. The upper connection wire 215 may be (electrically) connected to the upper bonding pad 220. The upper connection wire 215 may be (electrically) connected to a second semiconductor chip 20. For example, the upper connection wire 215 may (electrically) connect the upper bonding pad 220 to the second semiconductor chip 20.

The upper bonding pad 220 may be disposed on the lower bonding pad 120. The lower bonding pad 120 may be in contact with the upper bonding pad 220. For example, the upper surface of the lower bonding pad 120 may be in contact with the lower surface of the upper bonding pad 220. The lower bonding pad 120 and the upper bonding pad 220 may be coupled to each other. The lower bonding pad 120 may be (electrically) connected to the upper bonding pad 220.

Each of the lower bonding pad 120 and the upper bonding pad 220 may include a circular, elliptical, or polygonal shape (in a plan view). Hereinafter, it will be illustrated that each of the lower bonding pad 120 and the upper bonding pad 220 has a circular shape (in a plan view).

The lower bonding pad 120 may have a first width W1. The upper bonding pad 220 may have a second width W2. The first width W1 and the second width W2 may refer to a width in the first direction D1 or the second direction D2. In some embodiments, the first width W1 may be the same as (equal to) the second width W2.

Each of the lower bonding pad 120 and the upper bonding pad 220 may include a conductive metal. Each of the lower bonding pad 120 and the upper bonding pad 220 may include, for example, copper (Cu), tungsten (W), cobalt (Co), aluminum (Al), silver (Ag), platinum (Pt), ruthenium (Ru), and/or molybdenum (Mo).

The first semiconductor chip 10 may be disposed under (below) the third lower interlayer insulating film 112. The second semiconductor chip 20 may be disposed above (on) the third upper interlayer insulating film 212. The first semiconductor chip 10 may include a logic circuit, and the second semiconductor chip 20 may include memory cells. In some embodiments, the second semiconductor chip 20 may include a CMOS image sensor, and the first semiconductor chip 10 may include a logic circuit for controlling the operation of the CMOS image sensor. In some embodiments, each of the first semiconductor chip 10 and the second semiconductor chip 20 may include a logic circuit.

The alignment key AK may be disposed on (in) the scribe line region SLR. The alignment key AK may include a lower alignment pattern 140 and an upper alignment pattern 240.

The lower alignment pattern 140 may be disposed on (in) the first lower interlayer insulating film 110. The first lower interlayer insulating film 110 may expose an upper surface of the lower alignment pattern 140. For example, the first lower interlayer insulating film 110 may not cover (may not overlap in the third direction D3) the upper surface of the lower alignment pattern 140. The upper surface of the lower alignment pattern 140 may be disposed on the first surface 110_A of the first lower interlayer insulating film 110. In some embodiments, the upper surface of the lower alignment pattern 140 may be coplanar with the first surface 110_A of the first lower interlayer insulating film 110. The first upper interlayer insulating film 210 may be disposed on the upper surface of the lower alignment pattern 140.

The lower alignment pattern 140 may be disposed to be spaced apart from the lower bonding pad 120 in the first direction D1. In some embodiments, the upper surface of the lower alignment pattern 140 may be disposed at the same level as the upper surface of the lower bonding pad 120. By the expression “same”, it includes an error in the process. For example, a distance from the second surface 110_B of the first lower interlayer insulating film 110 to the upper surface of the lower bonding pad 120 (in the third direction D3) may be the same as (equal to) a distance from the second surface 110_B of the first lower interlayer insulating film 110 to the upper surface of the lower alignment pattern 140 (in the third direction D3). For example, the upper surface of the lower bonding pad 120 may be coplanar with the upper surface of the lower alignment pattern 140. Herein, the term “level”, “vertical level”, “height”, or the like may refer to a relative location with respect to a reference element in the third direction D3. A level, a vertical level, height, or the like may be a distance from the lower surface of the first semiconductor chip 10 in the third direction D3. For example, a higher level may mean a farther distance from the lower surface of the first semiconductor chip 10 in the third direction D3, and a lower level may mean a closer distance to the lower surface of the first semiconductor chip 10 in the third direction D3.

The upper alignment pattern 240 may be disposed on (in) the first upper interlayer insulating film 210. The first upper interlayer insulating film 210 may expose a lower surface of the upper alignment pattern 240. For example, the first upper interlayer insulating film 210 may not cover the lower surface of the upper alignment pattern 240. The lower surface of the upper alignment pattern 240 may be disposed on the first surface 210_A of the first upper interlayer insulating film 210. For example, the lower surface of the upper alignment pattern 240 may be coplanar with the first surface 210_A of the first upper interlayer insulating film 210. The first lower interlayer insulating film 110 may be disposed on the lower surface of the upper alignment pattern 240.

The upper alignment pattern 240 may be disposed to be spaced apart from the upper bonding pad 220 in the first direction D1. In some embodiments, the lower surface of the upper alignment pattern 240 may be disposed at the same level as the lower surface of the upper bonding pad 220. By the expression “same”, it includes an error in the process. For example, a distance from the second surface 210_B of the first upper interlayer insulating film 210 to the lower surface of the upper bonding pad 220 (in the third direction D3) may be the same as (equal to) a distance from the second surface 210_B of the first upper interlayer insulating film 210 to the lower surface of the upper alignment pattern 240 (in the third direction D3). For example, the lower surface of the upper bonding pad 220 may be coplanar with the lower surface of the upper alignment pattern 240.

The lower alignment pattern 140 and the upper alignment pattern 240 will be described in detail below with reference to FIGS. 3 to 5.

When viewed in a plan view, the lower alignment pattern 140 may have a circular ring shape. The lower alignment pattern 140 may include a first sub-lower alignment pattern 141, a second sub-lower alignment pattern 142, and a third sub-lower alignment pattern 143. Each of the first, second, and third sub-lower alignment patterns 141, 142, and 143 may have a closed shape. In some embodiments, the sub-lower alignment patterns (e.g., the first, second, and third sub-lower alignment patterns 141, 142, and 143) may be spaced apart from each other at the equal (regular) interval. The closed shape as used herein may refer to a shape of a ring such as a circular ring, an elliptical ring, a polygonal ring, etc. with a hollow interior, in which a start point and an end point are connected. For example, in a plan view, the second sub-lower alignment pattern 142 may extend around (e.g., at least partially surround) the first sub-lower alignment pattern 141, and the third sub-lower alignment pattern 143 may extend around (e.g., at least partially surround) the first sub-lower alignment pattern 141 and the second sub-lower alignment pattern 142. The second sub-lower alignment pattern 142 may be between the first sub-lower alignment pattern 141 and the third sub-lower alignment pattern 143 (in the first direction D1 and/or the second direction D2).

Each of the first, second, and third sub-lower alignment patterns 141, 142, and 143 may have a circular ring shape. Center portions (e.g., centers) of the first, second, and third sub-lower alignment patterns 141, 142, and 143 may be the same as each other (e.g., may be at the same location in a plan view). That is, the first, second, and third sub-lower alignment patterns 141, 142, and 143 may have a concentric shape (e.g., a concentric ring shape).

Each of the first, second, and third sub-lower alignment patterns 141, 142, and 143 may have the same (equal) width. For example, each of the first, second, and third sub-lower alignment patterns 141, 142, and 143 may have a third width W3. The third width W3 may be 10% to 300% of the first width W1 of the lower bonding pad 120. For example, if the first width W1 is 0.5 um, the third width W3 may be 0.05 um to 1.5 um. If the first width W1 is 1 μm, the third width W3 may be 0.1 μm to 3 μm.

The first, second, and third sub-lower alignment patterns 141, 142, and 143 may be spaced apart from each other. For example, the first sub-lower alignment pattern 141 may be spaced apart from the second sub-lower alignment pattern 142 by a first distance S1, and the second sub-lower alignment pattern 142 may be spaced apart from the third sub-lower alignment pattern 143 by the first distance S1. In some embodiments, the first distance S1 may be the same as (equal to) the third width W3.

The upper alignment pattern 240 may have a circular ring shape. The upper alignment pattern 240 may include a first sub-upper alignment pattern 241, a second sub-upper alignment pattern 242, and a third sub-upper alignment pattern 243. Each of the first, second, and third sub-upper alignment patterns 241, 242, and 243 may have a closed shape (e.g., a circular ring, an elliptical ring, a polygonal ring, etc.). In some embodiments, the sub-upper alignment patterns (e.g., the first, second, and third sub-upper alignment patterns 241, 242, and 243) may be spaced apart from each other at the equal (regular) interval. Each of the first, second, and third sub-upper alignment patterns 241, 242, and 243 may have a circular ring shape. The center portions (e.g., the centers) of the first, second, and third sub-upper alignment patterns 241, 242, and 243 may be the same as (equal to) each other. That is, the first to third sub-upper alignment patterns 241, 242, and 243 may have a concentric shape (e.g., a concentric ring shape). For example, in a plan view, the second sub-upper alignment pattern 242 may extend around (e.g., at least partially surround) the first sub-upper alignment pattern 241, and the third sub-upper alignment pattern 243 may extend around (e.g., at least partially surround) the first sub-upper alignment pattern 241 and the second sub-upper alignment pattern 242. The second sub-upper alignment pattern 242 may be between the first sub-upper alignment pattern 241 and the third sub-upper alignment pattern 243 (in the first direction D1 and/or the second direction D2).

A center portion (e.g., a center) of the upper alignment pattern 240 may be the same (may be at the same location in a plan view) as a center portion (e.g., a center) of the lower alignment pattern 140. For example, from a plan view as illustrated in FIG. 5, the center portion of the upper alignment pattern 240 may be the same as the center portion of the lower alignment pattern 140. The center portions (e.g., the centers) of the first, second, and third sub-lower alignment patterns 141, 142, and 143 and the center portions (e.g., the centers) of the first, second, and third sub-upper alignment patterns 241, 242, and 243 may be the same as each other (may be at the same location in a plan view).

Each of the first, second, and third sub-upper alignment patterns 241, 242, and 243 may have the same (equal) width. For example, each of the first, second, and third sub-upper alignment patterns 241, 242, and 243 may have a fourth width W4. The fourth width W4 may be 10% to 300% of the second width W2 of the upper bonding pad 220. For example, if the second width W2 is 0.5 um, the fourth width W4 may be 0.05 um to 1.5 um. If the second width W2 is 2 μm, the third width W4 may be 0.2 μm to 6 μm.

In some embodiments, the third width W3 of the first, second, and third sub-lower alignment patterns 141, 142, and 143 may be the same as (equal to) the fourth width W4 of the first, second, and third sub-upper alignment patterns 241, 242, and 243. However, embodiments are not limited thereto. For example, the third width W3 of the first, second, and third sub-lower alignment patterns 141, 142, and 143 may be different from the fourth width W4 of the first, second, and third sub-upper alignment patterns 241, 242, and 243.

The first, second, and third sub-upper alignment patterns 241, 242, and 243 may be spaced apart from each other. For example, the first sub-upper alignment pattern 241 may be spaced apart from the second sub-upper alignment pattern 242 by a second distance S2, and the second sub-upper alignment pattern 242 may be spaced apart from the third sub-upper alignment pattern 243 by the second distance S2. In some embodiments, the second distance S2 may be the same as (equal to) the fourth width W4.

In some embodiments, the second distance S2 may be the same as (equal to) the first distance S1. However, embodiments are not limited thereto. The second distance S2 may be different from the first distance S1.

Although it is illustrated that the lower alignment pattern 140 includes three sub-lower alignment patterns 141, 142, and 143, and the upper alignment pattern 240 includes three sub-upper alignment patterns 241, 242, and 243, embodiments are not limited thereto. For example, the number of sub-lower alignment patterns and the number of sub-upper alignment patterns may vary. In addition, the number of sub-lower alignment patterns may be different from the number of sub-upper alignment patterns.

Each of the lower alignment pattern 140 and the upper alignment pattern 240 may have a closed shape. As described above, each of the lower alignment pattern 140 and the upper alignment pattern 240 may have a circular ring shape. The shape of the upper alignment pattern 240 may be similar to the shape of the lower alignment pattern 140 but may differ in size. For example, as illustrated in FIG. 5, the cross-sectional area of the lower alignment pattern 140 may be greater than the cross-sectional area of the upper alignment pattern 240.

In some embodiments, a width BPW of the lower alignment pattern 140 may be the same as a width UPW of the upper alignment pattern 240. However, embodiments are not limited thereto. For example, the width BPW of the lower alignment pattern 140 may be different from the width UPW of the upper alignment pattern 240. According to FIG. 5, the width BPW may include three third widths W3 and two first distances S1, and the width UPW may include three fourth widths W4 and two second distances S2.

As illustrated in FIG. 5, when viewed in a plan view, the upper alignment pattern 240 may be disposed in the lower alignment pattern 140. For example, the lower alignment pattern 140 may extend around (e.g., at least partially surround) the upper alignment pattern 240. The lower alignment pattern 140 and the upper alignment pattern 240 may be disposed to be spaced apart from each other. A distance PS by which the lower alignment pattern 140 and the upper alignment pattern 240 are spaced apart from each other may be the same as (equal to) the width BPW of the lower alignment pattern 140. However, embodiments are not limited thereto. The distance PS by which the lower alignment pattern 140 and the upper alignment pattern 240 are spaced apart from each other may be different from the width BPW of the lower alignment pattern 140.

In some embodiments, a semiconductor device may be formed by forming the first semiconductor chip 10, the first wiring structure 100, and the lower alignment pattern 140 on a first wafer, forming the second semiconductor chip 20, the second wiring structure 200, and the upper alignment pattern 240 on a second wafer, and aligning and coupling the first wafer and the second wafer. For example, the lower bonding pad 120 and the upper bonding pad 220 may be coupled to each other. Alignment of the lower alignment pattern 140 and the upper alignment pattern 240 may be performed to align the first wafer and the second wafer.

If the width of the lower alignment pattern 140 is excessively greater than the width of the lower bonding pad 120, the upper surface of the lower alignment pattern 140 may be disposed at a higher level than the upper surface of the lower bonding pad 120. In addition, if the width of the upper alignment pattern 240 is excessively greater than the width of the upper bonding pad 220, the lower surface of the upper alignment pattern 240 may be disposed at a lower level than the upper surface of the upper bonding pad 220. In this case, the first lower interlayer insulating film 110 and the first upper interlayer insulating film 210 may not be coupled to each other, or an air gap may be formed between the first lower interlayer insulating film 110 and the first upper interlayer insulating film 210, resulting in defects such as cracks.

In a semiconductor device according to some embodiments, the width of the lower alignment pattern 140 in one direction may be 10% to 300% of the width of the lower bonding pad 120 in one direction. In addition, the width of the upper alignment pattern 240 in one direction may be 10% to 300% of the width of the upper bonding pad 220 in one direction. The width of the lower alignment pattern 140 in one direction may be formed within a certain percentage of the width of the lower bonding pad 120 in one direction, such that a surface with a reduced step in the chemical mechanical polishing (CMP) process may be formed.

Accordingly, the upper surface of the lower bonding pad 120, the upper surface of the lower alignment pattern 140, the lower surface of the upper bonding pad 220, and the lower surface of the upper alignment pattern 240 may be disposed at a relatively similar or the same level after a planarization process such as CMP. As a result, the first wafer and the second wafer may be stably coupled to each other. For example, the first lower interlayer insulating film 110 and the first upper interlayer insulating film 210 may be stably coupled to each other, and electrical characteristics and reliability of the semiconductor device may be improved.

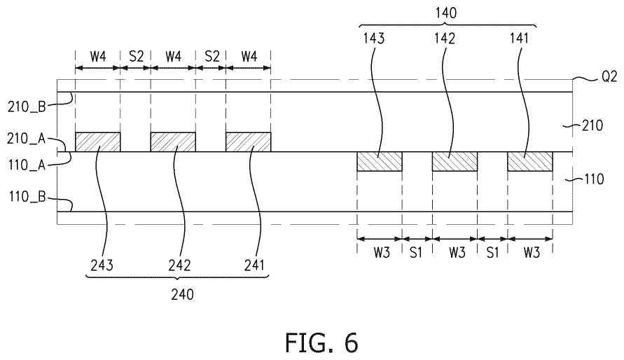

FIG. 6 is a diagram provided to explain a semiconductor device according to some embodiments. For convenience of description, differences from the configurations described above in FIGS. 1 to 5 will be mainly described. For reference, FIG. 6 may correspond to an enlarged view of the region Q2 of FIG. 2.

Referring to FIG. 6, in a semiconductor device according to some embodiments, each of the first, second, and third sub-lower alignment patterns 141, 142, and 143 may have the third width W3. The first, second, and third sub-lower alignment patterns 141, 142, and 143 may be spaced apart from each other. For example, the first sub-lower alignment pattern 141 may be spaced apart from the second sub-lower alignment pattern 142 by the first distance S1, and the second sub-lower alignment pattern 142 may be spaced apart from the third sub-lower alignment pattern 143 by the first distance S1. The first distance S1 may be smaller (less) than the third width W3.

Each of the first, second, and third sub-upper alignment patterns 241, 242, and 243 may have the fourth width W4. The first, second, and third sub-upper alignment patterns 241, 242, and 243 may be spaced apart from each other. For example, the first sub-upper alignment pattern 241 may be spaced apart from the second sub-upper alignment pattern 242 by a second distance S2, and the second sub-upper alignment pattern 242 may be spaced apart from the third sub-upper alignment pattern 243 by the second distance S2. The second distance S2 may be smaller (less) than the fourth width W4.

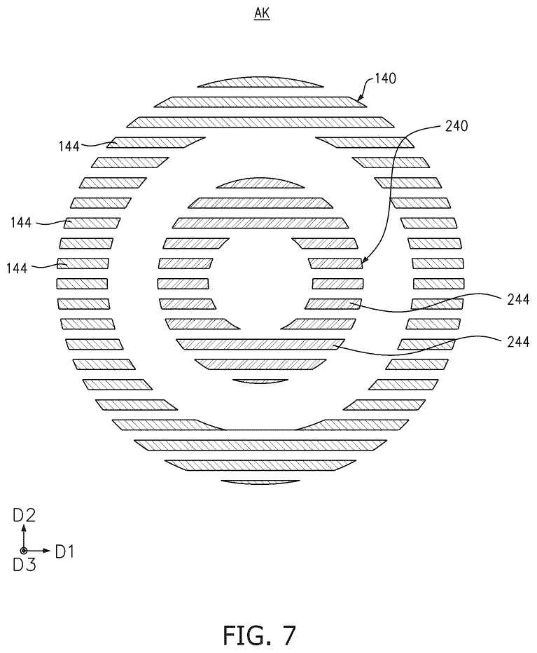

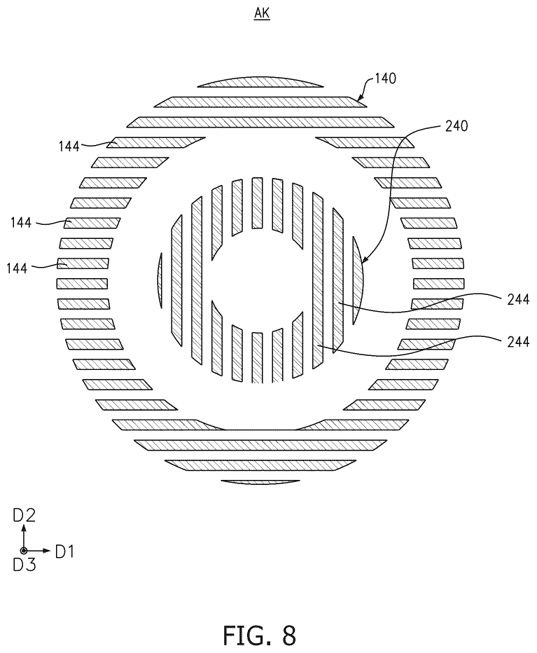

FIGS. 7 and 8 are diagrams provided to explain the alignment key of the semiconductor device according to some embodiments. For convenience of description, different configurations from those described above in FIGS. 1 to 5 will be mainly described. For reference, FIGS. 7 and 8 are plan views provided to explain the alignment key AK of FIG. 1.

Referring to FIGS. 7 and 8, in a semiconductor device according to some embodiments, the lower alignment pattern 140 may include a plurality of fourth sub-lower alignment patterns 144, and the upper alignment pattern 240 may include a plurality of fourth sub-upper alignment patterns 244.

Each of the fourth sub-lower alignment patterns 144 may include a linear shape extending in one direction. For example, each of the fourth sub-lower alignment patterns 144 may include a linear shape extending in the first direction D1. The width of each of the fourth sub-lower alignment patterns 144 may be 10% to 300% of the width W1 of the lower bonding pad 120 of FIG. 3. The width of the fourth sub-lower alignment pattern 144 may refer to a width in the second direction D2, which is a direction intersecting with a direction in which the fourth sub-lower alignment pattern 144 extends.

Each of the fourth sub-upper alignment patterns 244 may include a linear shape extending in one direction. For example, as illustrated in FIG. 7, each of the fourth sub-upper alignment patterns 244 may include a linear shape extending in the first direction D1. The width of each of the fourth sub-upper alignment patterns 244 may be 10% to 300% of the width W2 of the upper bonding pad 220 of FIG. 3. The width of the fourth sub-upper alignment pattern 244 may refer to a width in the second direction D2, which is a direction intersecting with the direction in which the fourth sub-upper alignment pattern 244 extends.

As another example, as illustrated in FIG. 8, each of the fourth sub-upper alignment patterns 244 may include a linear shape extending in the second direction D2. The width of each of the fourth sub-upper alignment patterns 244 may be 10% to 300% of the width W2 of the upper bonding pad 220 of FIG. 3. The width of the fourth sub-upper alignment pattern 244 may refer to a width in the first direction D1, which is a direction intersecting with the direction in which the fourth sub-upper alignment pattern 244 extends. For example, the fourth sub-upper alignment patterns 244 and the fourth sub-lower alignment patterns 144 may extend in different directions.

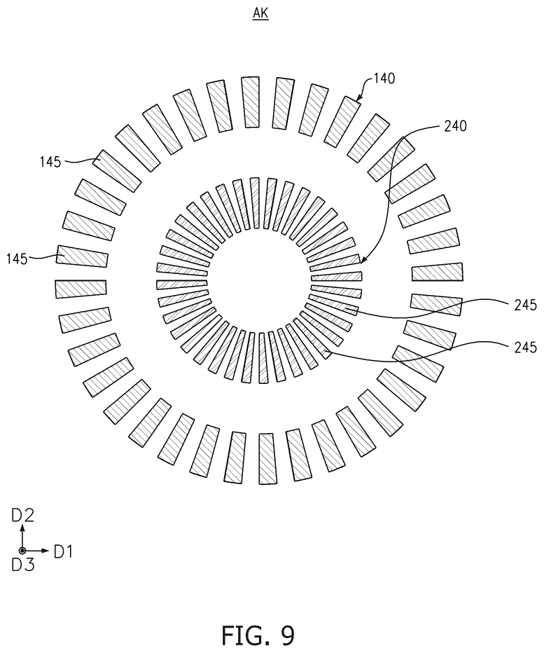

FIG. 9 is a diagram provided to explain the alignment key of the semiconductor device according to some embodiments. For convenience of description, different configurations from those described above in FIGS. 1 to 5 will be mainly described. For reference, FIG. 9 is a plan view provided to explain the alignment key AK of FIG. 1.

Referring to FIG. 9, in a semiconductor device according to some embodiments, the lower alignment pattern 140 may include a plurality of fifth sub-lower alignment patterns 145, and the upper alignment pattern 240 may include a plurality of fifth sub-upper alignment patterns 245.

The overall shape of the lower alignment pattern 140 may be circular (e.g., a ring shape in a plan view). The plurality of fifth sub-lower alignment patterns 145 may be disposed to be spaced apart from each other to form a circular shape (e.g., a ring shape in a plan view). At least one of the plurality of fifth sub-lower alignment patterns 145 may include a linear shape extending in one direction. The one direction may be a direction passing through the center portion (e.g., the center) of the lower alignment pattern 140. Each of the plurality of fifth sub-lower alignment patterns 145 may be disposed along a circumference of a virtual circle having the center portion (e.g., the center) of the lower alignment pattern 140 as a center portion (e.g., a center) of the circle. For example, the plurality of fifth sub-lower alignment patterns 145 may be arranged like the spokes of a wheel so that the lower alignment pattern 140 may have a radial ring shape.

The width of the fifth sub-lower alignment pattern 145 may be changed. For example, the width in the direction perpendicular to the center portion (e.g., the center) of the circle (e.g., the width in the direction that is perpendicular to the one direction passing through the center portion (e.g., the center) of the lower alignment pattern 140) may be changed (may have various values), but each of the various values of the width of the fifth sub-lower alignment pattern 145 may fall within the range of 10% to 300% of the width W1 of the lower bonding pad (e.g., the lower bonding pad 120 of FIG. 3).

The upper alignment patterns 240 may form a circular shape (e.g., a ring shape in a plan view). The plurality of fifth sub-upper alignment patterns 245 may be disposed to be spaced apart from each other to form a circular shape (e.g., a ring shape in a plan view). At least one of the plurality of the fifth sub-upper alignment pattern 245 may include a linear shape extending in one direction. The one direction may be a direction passing through the center portion (e.g., the center) of the upper alignment pattern 240 (and/or the center portion (e.g., the center) of the lower alignment pattern 140). Each of the plurality of fifth sub-upper alignment patterns 245 may be disposed along a circumference of a virtual circle having the center portion (e.g., the center) of the upper alignment pattern 240 as a center portion (e.g., a center) of the circle. For example, the plurality of fifth sub-upper alignment patterns 245 may be arranged like the spokes of a wheel so that the upper alignment pattern 240 may have a radial ring shape.

The width of the fifth sub-upper alignment pattern 245 may be changed.

For example, the width in the direction perpendicular to the center portion (e.g., the center) of the circle (e.g., the width in the direction that is perpendicular to the one direction passing through the center portion (e.g., the center) of the upper alignment pattern 240) may be changed (may have various values), but each of the various values of the width of the fifth sub-upper alignment pattern 245 may fall within the range of 10% to 300% of the width W2 of the upper bonding pad (e.g., the upper bonding pad 220 of FIG. 3).

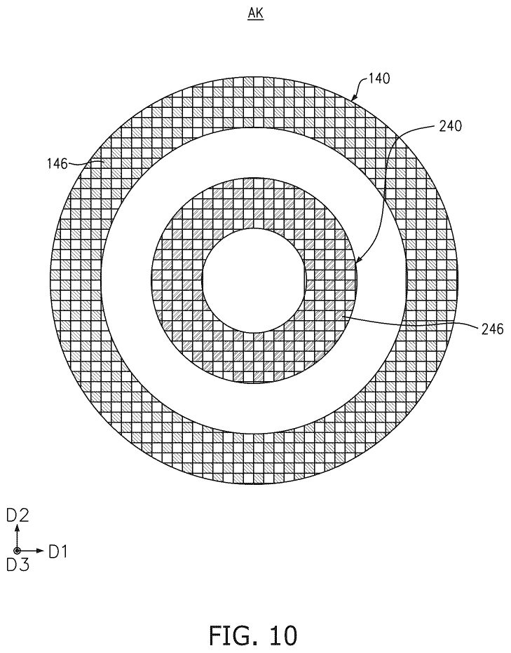

FIG. 10 is a diagram provided to explain an alignment key of a semiconductor device according to some embodiments. For convenience of description, differences from the configurations described above in FIGS. 1 to 5 will be mainly described. For reference, FIG. 10 is a plan view provided to explain the alignment key AK of FIG. 1.

Referring to FIG. 10, in a semiconductor device according to some embodiments, the lower alignment pattern 140 may include a plurality of sixth sub-lower alignment patterns 146, and the upper alignment pattern 240 may include a plurality of sixth sub-upper alignment patterns 246.

The plurality of sixth sub-lower alignment patterns 146 may be repeatedly arranged patterns. For example, the plurality of sixth sub-lower alignment patterns 146 may be quadrangular grid patterns (e.g., lattice patterns) disposed to be spaced apart from each other. In some embodiments, the plurality of sixth sub-lower alignment patterns 146 may be circular dot patterns disposed to be spaced apart from each other.

The plurality of sixth sub-upper alignment patterns 246 may be repeatedly arranged patterns. For example, the plurality of sixth sub-upper alignment patterns 246 may be quadrangular grid patterns (e.g., lattice patterns) disposed to be spaced apart from each other. In some embodiments, the plurality of sixth sub-upper alignment patterns 246 may be circular dot patterns disposed to be spaced apart from each other.

Description of the width of the sixth sub-lower alignment pattern 146 and the width of the sixth sub-upper alignment pattern 246 may be the same as or similar to that described above in conjunction with FIGS. 2 to 5.

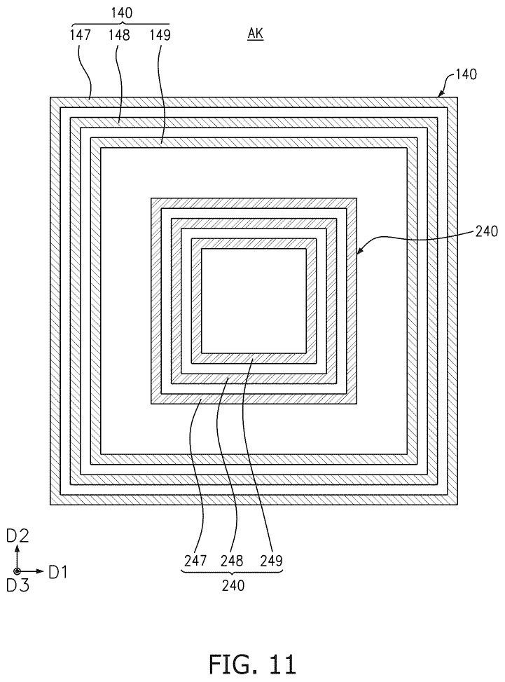

FIG. 11 is a diagram provided to explain an alignment key of a semiconductor device according to some embodiments. For convenience of description, differences from the configurations described above in FIGS. 1 to 5 will be mainly described. For reference, FIG. 11 is a plan view provided to explain the alignment key AK of FIG. 1.

Referring to FIG. 11, in a semiconductor device according to some embodiments, each of the lower alignment pattern 140 and the upper alignment pattern 240 may have a closed shape. Each of the lower alignment pattern 140 and the upper alignment pattern 240 may have a quadrangular shape.

The lower alignment pattern 140 may include seventh, eighth, and ninth sub-lower alignment patterns 147, 148, and 149. Each of the seventh, eighth, and ninth sub-lower alignment patterns 147, 148, and 149 may have a closed shape. The seventh, eighth, and ninth sub-lower alignment patterns 147, 148, and 149 may have a quadrangular ring shape. The center portions (e.g., the centers) of the seventh, eighth, and ninth sub-lower alignment patterns 147, 148, and 149 may be the same as each other (may be at the same location in a plan view).

Each of the seventh, eighth, and ninth sub-lower alignment patterns 147, 148, and 149 may have the same width. The seventh, eighth, and ninth sub-lower alignment patterns 147, 148, and 149 may be disposed to be spaced apart from each other.

The upper alignment pattern 240 may include seventh, eighth, and ninth sub-upper alignment patterns 247, 248, and 249. Each of the seventh, eighth, and ninth sub-upper alignment patterns 247, 248, and 249 may have a closed shape. The seventh, eighth, and ninth sub-upper alignment patterns 247, 248, and 249 may have a quadrangular ring shape. The center portions (e.g., the centers) of the seventh, eighth, and ninth sub-upper alignment patterns 247, 248, and 249 may be the same as each other (may be at the same location in a plan view).

Each of the seventh, eighth, and ninth sub-upper alignment patterns 247, 248, and 249 may have the same width. The seventh, eighth, and ninth sub-upper alignment patterns 247, 248, and 249 may be disposed to be spaced apart from each other.

Description of a width of each of the seventh, eighth, and ninth sub-lower alignment patterns 147, 148, and 149 and description of a width of each of the seventh, eighth, and ninth sub-upper alignment patterns 247, 248, and 249 may be the same as the description of the widths of the first, second, and third sub-lower alignment patterns 141, 142, and 143 and the first, second, and third sub-upper alignment patterns 241, 242, and 243 described above in FIGS. 2 to 5.

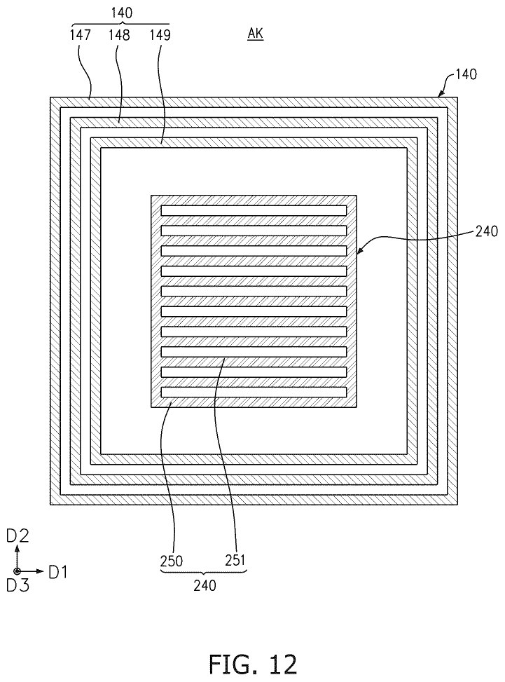

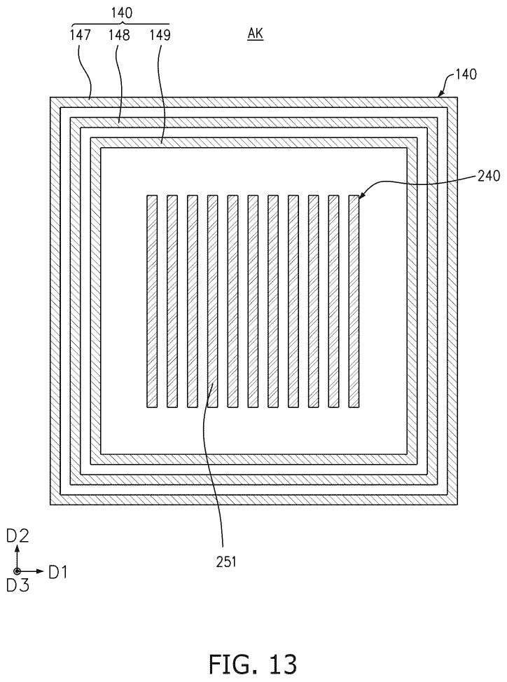

FIGS. 12 and 13 are diagrams provided to explain the alignment key of the semiconductor device according to some embodiments. For convenience of description, differences from the configurations described above with reference to FIGS. 1 to 5 and 11 will be mainly described. For reference, FIGS. 12 and 13 are plan views provided to explain the alignment key AK of FIG. 1.

Referring to FIG. 12, in a semiconductor device according to some embodiments, the upper alignment pattern 240 may include a tenth sub-upper alignment pattern 250 and a plurality of eleventh sub-upper alignment patterns 251.

The tenth sub-upper alignment pattern 250 may have a quadrangular shape. The tenth sub-upper alignment pattern 250 may define (may constitute) a circumference of the upper alignment pattern 240.

The plurality of eleventh sub-upper alignment patterns 251 may be disposed inside the tenth sub-upper alignment pattern 250. The plurality of eleventh sub-upper alignment patterns 251 may have a linear shape extending in one direction. For example, the plurality of eleventh sub-upper alignment patterns 251 may have a linear shape extending in the first direction D1. In this case, the plurality of eleventh sub-upper alignment patterns 251 may be disposed to be spaced apart from each other in the second direction D2.

Referring to FIG. 13, in a semiconductor device according to some embodiments, unlike FIG. 12, the upper alignment pattern 240 may not include the tenth sub-upper alignment pattern 250. The upper alignment pattern 240 may include the plurality of eleventh sub-upper alignment patterns 251. The plurality of eleventh sub-upper alignment patterns 251 may have a linear shape extending in one direction. For example, the plurality of eleventh sub-upper alignment patterns 251 may have a linear shape extending in the second direction D2. In this case, the plurality of eleventh sub-upper alignment patterns 251 may be disposed to be spaced apart from each other in the first direction D1.

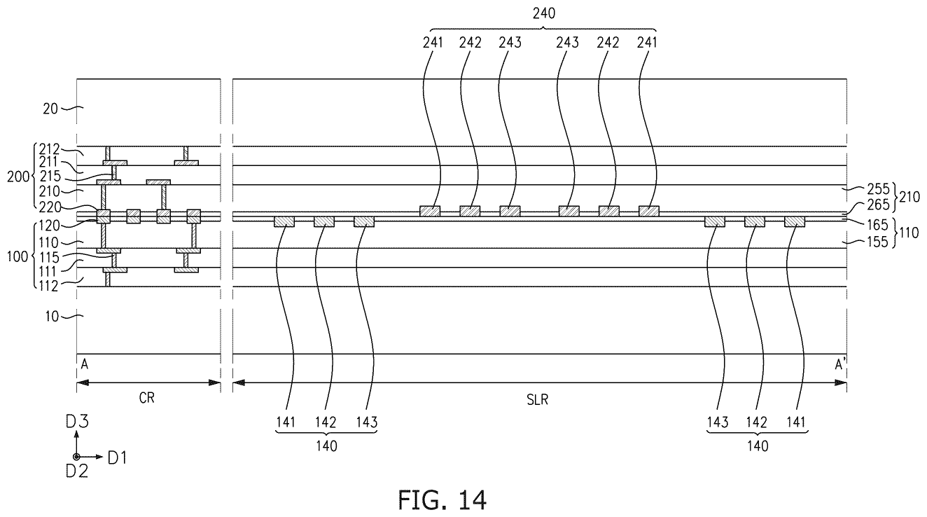

FIG. 14 is a diagram provided to explain a semiconductor device according to some embodiments. For convenience of description, differences from the configurations described above in FIGS. 1 to 5 will be mainly described. For reference, FIG. 14 may correspond to a cross-sectional view taken along line A-A′ of FIG. 1.

Referring to FIG. 14, in a semiconductor device according to some embodiments, the first lower interlayer insulating film 110 may include a first insulating layer 155 and a first bonding layer 165.

The first bonding layer 165 may be disposed above (on) the first insulating layer 155. An upper surface of the first bonding layer 165 may define (may be) an upper surface of the first lower interlayer insulating film 110. The first bonding layer 165 may expose the upper surface of the lower alignment pattern 140. For example, the upper surface of the first bonding layer 165 may be coplanar with the upper surface of the lower alignment pattern 140. The first bonding layer 165 may overlap the lower alignment pattern 140 in the first direction D1.

The first upper interlayer insulating film 210 may include a second insulating layer 255 and a second bonding layer 265. The second bonding layer 265 may be disposed under (below) the second insulating layer 255. A lower surface of the second bonding layer 265 may define (may be) a lower surface of the first upper interlayer insulating film 210. The second bonding layer 265 may expose the lower surface of the upper alignment pattern 240. For example, the lower surface of the second bonding layer 265 may be coplanar with the lower surface of the upper alignment pattern 240. The second bonding layer 265 may overlap the upper alignment pattern 240 in the first direction D1.

The first bonding layer 165 may be in contact with the second bonding layer 265. Each of the first bonding layer 165 and the second bonding layer 265 may include an insulating material. Each of the first bonding layer 165 and the second bonding layer 265 may include, for example, silicon nitride, silicon oxynitride, silicon carbonitride, and/or silicon oxycarbide nitride. However, embodiments are not limited thereto.

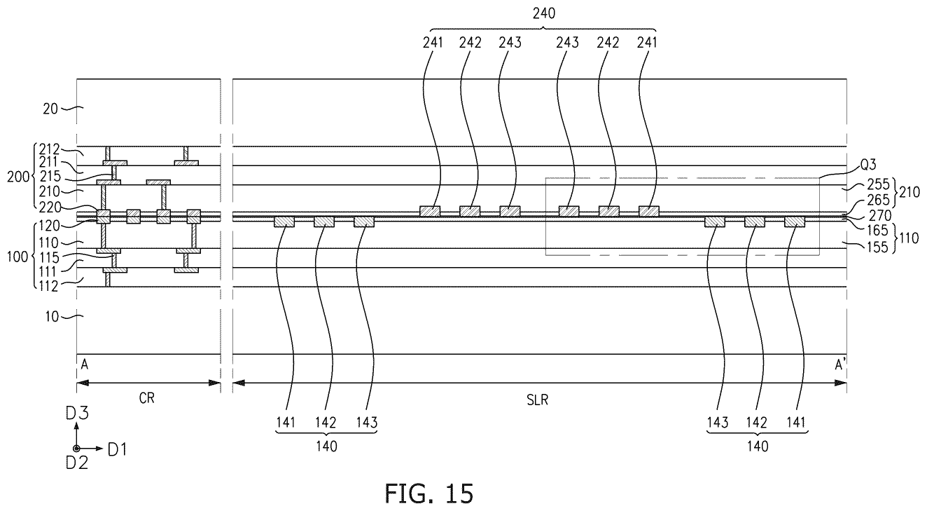

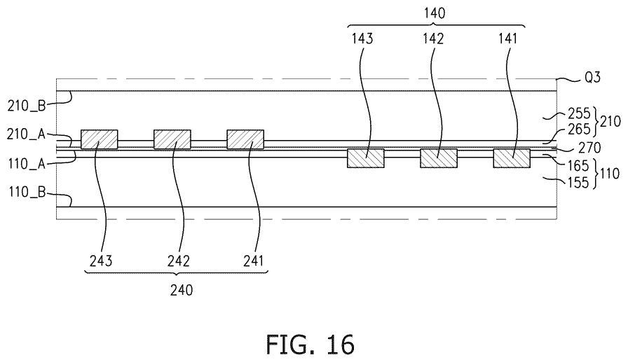

FIGS. 15 and 16 are diagrams provided to explain a semiconductor device according to some embodiments. For convenience of description, differences from the configurations described above with reference to FIGS. 1 to 5 and 14 will be mainly described. For reference, FIG. 15 may correspond to a cross-sectional view taken along line A-A′ of FIG. 1, and FIG. 16 is an enlarged view provided to explain the region Q3 of FIG. 15.

Referring to FIGS. 15 and 16, the semiconductor device according to some embodiments may further include a bonding oxide film 270.

The bonding oxide film 270 may be disposed between the first bonding layer 165 and the second bonding layer 265 (in the third direction D3). The first bonding layer 165 and the second bonding layer 265 may be spaced apart from each other by the bonding oxide film 270. That is, the first bonding layer 165 and the second bonding layer 265 may not be in contact with each other. A thickness of the bonding oxide film 270 may be less than a thickness of the first bonding layer 165 and a thickness of the second bonding layer 265. The thickness may refer to a thickness in the third direction D3.

In some embodiments, a portion of the bonding oxide film 270 may be disposed between the first bonding layer 165 and the upper alignment pattern 240. A portion of the bonding oxide film 270 may be disposed between the second bonding layer 265 and the lower alignment pattern 140. The bonding oxide film 270 may include, for example, a silicon oxide film.

Rather than the bonding oxide film 270 defining the upper or lower surface of the interlayer insulating film, the upper surface of the first bonding layer 165 may define the upper surface of the first lower interlayer insulating film 110, and the lower surface of the second bonding layer 265 may define the lower surface of the first upper interlayer insulating film 210. The first bonding layer 165 may expose the upper surface of the lower alignment pattern 140. The second bonding layer 265 may expose the lower surface of the upper alignment pattern 240. The bonding oxide film 270 may be on (cover or overlap in the third direction D3) the upper surface of the lower alignment pattern 140 and the lower surface of the upper alignment pattern 240.

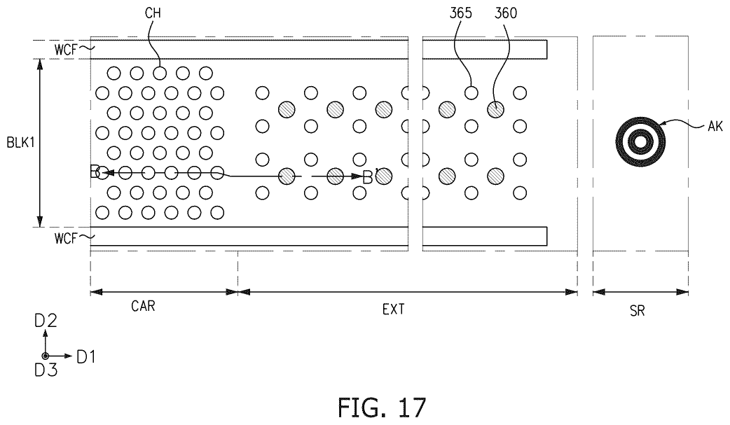

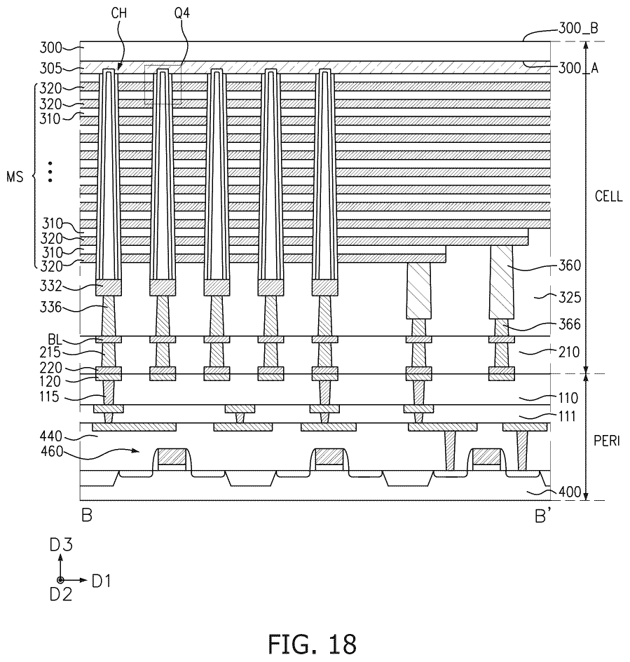

FIG. 17 is a diagram provided to explain a semiconductor device according to some embodiments. FIG. 18 is a cross-sectional view taken along line B-B′ of FIG. 17.

Referring to FIGS. 17 and 18, the semiconductor device according to some embodiments may include a cell structure CELL and a peripheral circuit structure PERI.

The cell structure CELL may include a cell substrate 300, a common source plate 305, a mold structure MS, a channel structure CH, a bit line BL, a word line contact 360, the upper connection wire 215, etc.

The cell substrate 300 may include a cell array region CAR and an extension region EXT.

A memory cell array including a plurality of memory cells may be formed on the cell array region CAR. The channel structure CH, the mold structure MS, the bit line BL, etc. may be disposed on the cell array region CAR.

The extension region EXT may be disposed around the cell array region CAR. In some embodiments, the extend region EXT may be adjacent the cell array region CAR. For example, the extension region EXT may extend around (e.g., at least partially surround) the cell array region CAR. The word line contact 360, a dummy channel structure 365, etc. may be disposed on the extension region EXT. In some embodiments, the cell array region CAR and the extension region EXT may form the chip region CR of FIG. 1.

The scribe lane region SLR may be disposed around the extension region EXT. In some embodiments, the scribe lane region SLR may be adjacent the extension region EXT. For example, the scribe lane region SLR may extend around (at least partially surround) the extension region EXT. An alignment key AK may be disposed on (in) the scribe lane region SLR. FIG. 17 illustrates the alignment key AK described in FIG. 5, but this should be interpreted as an example. For example, the semiconductor device of FIG. 17 may include any one of the alignment keys AK described above in FIGS. 5 to 13.

For example, the cell substrate 300 may include a semiconductor substrate such as a silicon substrate, a germanium substrate, and/or a silicon-germanium substrate. In some embodiments, the cell substrate 300 may include a silicon-on-insulator (SOI) substrate, a germanium-on-insulator (GOI) substrate, etc. In some embodiments, the cell substrate 300 may include polysilicon (poly Si).

The cell substrate 300 may include a first surface 300_A and a second surface 300_B opposite to the first surface 300_A (in the third direction D3). The first surface 300_A of the cell substrate 300 may refer to a surface on which the mold structure MS and the channel structure CH are disposed. The first surface 300_A of the cell substrate 300 may be referred to as a front side of the cell substrate 300. The second surface 300_B of the cell substrate 300 may be referred to as a back side of the cell substrate 300.

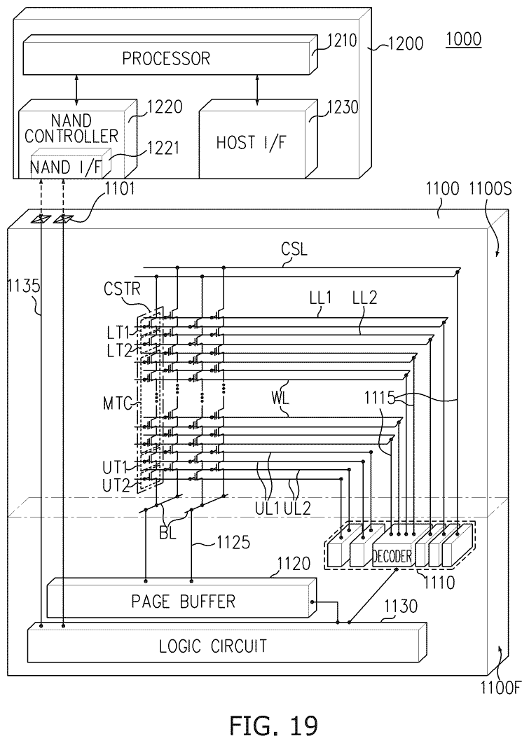

The common source plate 305 may be disposed on the first surface 300_A of the cell substrate 300. The common source plate 305 may be disposed on the cell region CAR and the extension region EXT. The common source plate 305 may be connected to the channel structure CH. For example, the common source plate 305 may be electrically connected to a channel layer of the channel structure CH. The common source plate 305 may be provided as a common source line (e.g., CSL of FIG. 19) of the semiconductor memory device. For example, the common source plate 305 may include polycrystalline silicon and/or metal doped with an impurity, but embodiments are not limited thereto.

The mold structure MS may be disposed on the common source plate 305. The mold structure MS may be disposed on the cell array region CAR and the extension region EXT of the cell substrate 300. The mold structure MS may include a plurality of mold insulating layers 310 and a plurality of gate electrodes 320 alternately stacked in the third direction D3. Each of the mold insulating layers 310 and each of the gate electrodes 320 may have a layered structure extending parallel to the first surface 300_A of the cell substrate 300. The gate electrodes 320 may be sequentially stacked on the common source plate 305 and spaced apart from each other by the mold insulating layers 310.

In some embodiments, some of the plurality of gate electrodes 320 may be provided as a ground select line GSL of a semiconductor memory device. Some gate electrodes 320 of the plurality of gate electrodes 320 may be provided as a string select line SSL of the semiconductor memory device. For example, a gate electrode 320 of the plurality of gate electrodes 320 that is adjacent to (e.g., closest to) the common source plate 305 may be provided as the ground select line GSL. A gate electrode 320 of the plurality of gate electrodes 320 that is adjacent to (e.g., closest to) the bit line BL may be provided as a string select line SSL. However, embodiments are not limited thereto. The arrangement and number of the ground select lines GSL and the string select lines SSL may vary.

The mold insulating layer 310 may include an insulating material. For example, the mold insulating layer 310 may include silicon oxide, silicon nitride, and/or silicon oxynitride, but embodiments are not limited thereto.

The gate electrode 320 may include a conductive material. For example, the gate electrode 320 may include a metal such as tungsten (W), cobalt (Co), nickel (Ni), and/or a semiconductor material such as silicon, but embodiments are not limited thereto.

A cell interlayer insulating film 325 may be formed on the first surface 300_A of the cell substrate 300. The cell interlayer insulating film 325 may be disposed on the mold structure MS, covering (or overlapping) the mold structure MS. For example, the cell interlayer insulating film 325 may include silicon oxide, silicon oxynitride, and/or a low-k material having a lower dielectric constant than silicon oxide, but embodiments are not limited thereto.

The channel structure CH may be disposed on the cell array region CAR of the cell substrate 300. The channel structure CH may extend in the third direction D3, that is, in a direction perpendicular to the first surface 300_A of the cell substrate 300. The channel structure CH may be formed in (through) the mold structure MS. For example, the channel structure CH may be formed to extend into (through) and intersect each of the plurality of gate electrodes 320. The channel structure CH may have a pillar shape (e.g., a cylindrical shape) extending in the third direction D3. In some embodiments, the cross section of the channel structure CH may have an inclined side surface such that its width is progressively narrowed toward the cell substrate 300. However, embodiments are not limited thereto.

In some embodiments, the channel structure CH may include a filling insulating layer, a channel layer, and an information storage film.

The channel layer may extend in the third direction D3 and be formed through (in) the mold structure MS. The channel layer may have various shapes such as a cylindrical shape, a quadrangular cylindrical shape, and a solid pillar shape. The channel layer may include, for example, a semiconductor material such as single crystal silicon, polycrystalline silicon, an organic semiconductor material, and a carbon nanostructure, but embodiments are not limited thereto.

The information storage film may be interposed between the channel layer and each of the gate electrodes 320. For example, the information storage film may extend along an outer surface of the channel layer. For example, the information storage film may include silicon oxide, silicon nitride, silicon oxynitride, and/or a high-k material having a higher dielectric constant than the silicon oxide. For example, the high-k material may include aluminum oxide, hafnium oxide, lanthanum oxide, tantalum oxide, titanium oxide, lanthanum hafnium oxide, lanthanum aluminum oxide, dysprosium scandium oxide, and/or a combination thereof.

In some embodiments, the channel structures CH may be arranged in a zigzag form in a plan view. For example, as illustrated in FIG. 17, the channel structures CH may be disposed alternately in the first and second directions D1 and D2. The channel structures CH arranged in the zigzag form may further improve the integration density of the semiconductor memory device. In some embodiments, the channel structures CH may be arranged in a honeycomb form.

In some embodiments, the information storage film may be formed of multiple films. The information storage film may include a tunnel insulating film, a charge storage film, and a blocking insulating film sequentially stacked on the outer surface of the channel layer.

For example, the tunnel insulating film may include a silicon oxide and/or a high-k material (e.g., aluminum oxide (Al2O3), hafnium oxide (HfO2)) having a higher dielectric constant than the silicon oxide. For example, the charge storage film may include a silicon nitride. For example, the blocking insulating film may include a silicon oxide and/or a high-k material (e.g., aluminum oxide (Al2O3) or hafnium oxide (HfO2)) having a higher dielectric constant than the silicon oxide.

In some embodiments, the channel structure CH may further include a filling insulating layer. The filling insulating layer may be formed to fill the inside of channel layer which may have a cup shape. For example, the filling insulating layer may include an insulating material such as silicon oxide, but embodiments are not limited thereto.

In some embodiments, a channel pad 332 may be disposed on the channel structure CH. The channel pad 332 may be formed to be (electrically) connected to the channel layer (of the channel structure CH). For example, the channel pad 332 may be provided in the cell interlayer insulating film 325 to be (electrically) connected to one end of the channel layer. For example, the channel pad 332 may include polysilicon doped with an impurity, but embodiments are not limited thereto.

The mold structure MS may be divided by word line cutting regions WCF to form a memory cell block (e.g., BLK1 of FIG. 17). The word line cutting region WCF may include an insulating material, for example, silicon oxide, silicon nitride, and/or silicon oxynitride, but embodiments are not limited thereto.

The bit lines BL may be formed on the mold structure MS. The bit lines BL may intersect (overlap in the third direction D3) the word line cutting regions WCF. For example, each of the bit lines BL may extend in the second direction D2. The bit lines BL may be disposed along the first direction D1 while being spaced apart from each other.

The bit lines BL may be (electrically) connected to the channel structures CH disposed along the second direction D2. A bit line contact 336 may be formed in the cell interlayer insulating film 325. The bit line BL may be electrically connected to the channel structure CH through the bit line contact 336 and the channel pad 332.

The word line contact 360 may be disposed on (in) the extension region EXT of the cell substrate 300. For example, the word line contact 360 may be disposed on a staircase structure of the gate electrodes 320. The word line contact 360 may extend in the third direction D3 and may be (electrically) connected to the gate electrode 320.

The dummy channel structure 365 may be disposed on (in) the extension region EXT of the cell substrate 300. The dummy channel structure 365 may be disposed around (adjacent) the word line contact 360. The dummy channel structure 365 may include an insulating material. For example, the dummy channel structure 365 may include a silicon oxide-based insulating material. However, embodiments are not limited thereto.

The upper connection wire 215 may be formed on the mold structure MS. For example, the first upper interlayer insulating film 210 may be formed on the cell interlayer insulating film 325, and the upper connection wire 215 may be formed in the first upper interlayer insulating film 210. The upper connection wire 215 may be electrically connected to the bit line BL and the word line contact 360. As a result, the upper connection wire 215 may be electrically connected to the channel structure CH and the gate electrode 320. The number, arrangement, etc. of the layers of the upper connection wire 215 are illustrative only, and embodiments are not limited thereto.

The peripheral circuit structure PERI may include a peripheral circuit substrate 400, a peripheral circuit element 460, and the lower connection wire 115.

For example, the peripheral circuit substrate 400 may include a semiconductor substrate such as a silicon substrate, a germanium substrate, a silicon-germanium substrate, etc. In some embodiments, the peripheral circuit substrate 400 may include a silicon-on-insulator (SOI) substrate, a germanium-on-insulator (GOI) substrate, etc.

The peripheral circuit element 460 may be formed on (in) the peripheral circuit substrate 400. The peripheral circuit element 460 may configure a peripheral circuit that controls the operation of the semiconductor memory device. For example, the peripheral circuit element 460 may include a logic circuit 1130, a page buffer 1120, a decoder circuit 1110, etc. of FIG. 19. In the following description, the surface of the peripheral circuit substrate 400 on which the peripheral circuit element 460 is disposed may be referred to as a front side of the peripheral circuit substrate 400. Conversely, the surface of the peripheral circuit substrate 400 opposite to the front side of the peripheral circuit substrate 400 may be referred to as a back side of the peripheral circuit substrate 400.

For example, the peripheral circuit element 460 may include a transistor, but embodiments are not limited thereto. For example, the peripheral circuit element 460 may include not only various active elements such as transistors, etc., but also various passive elements such as capacitors, resistors, inductors, etc.

The lower connection wire 115 may be formed on the peripheral circuit element 460. For example, a peripheral interlayer insulating film 440, the first lower interlayer insulating film 110, and the second lower interlayer insulating film 111 may be formed on the front side of the peripheral circuit substrate 400. The lower connection wire 115 may be formed in the first lower interlayer insulating film 110 and the second lower interlayer insulating film 111. The lower connection wire 115 may be electrically connected to the peripheral circuit element 460. The number, arrangement, etc. of the layers of the lower connection wire 115 are illustrative only, and embodiments are not limited thereto.

The semiconductor memory device according to some embodiments may have a chip-to-chip (C2C) structure. The C2C structure refers to manufacturing an upper chip including the cell structure (CELL) on a first wafer (e.g., the cell substrate 300), manufacturing a lower chip including the peripheral circuit structure (PERI) on a second wafer (e.g., the peripheral circuit substrate 400) that is different from the first wafer, and connecting the upper and lower chips to each other by a bonding method.

In some embodiments, the bonding method may refer to a method of electrically connecting the upper bonding pad 220 formed on the uppermost metal layer of the upper chip (e.g., on the first surface 300_A of the cell substrate 300 in FIG. 18) and the lower bonding pad 120 formed on the uppermost metal layer of the lower chip (on the front side of the peripheral circuit substrate 400 in FIG. 18) to each other. For example, if the upper bonding pad 220 and the lower bonding pad 120 are formed of copper (Cu), the bonding method may be a Cu—Cu bonding method. However, this is only an example. The upper bonding pad 220 and the lower bonding pad 120 may include (e.g., may be formed of) various metals such as aluminum (Al), tungsten (W), etc.

As the upper bonding pad 220 and the lower bonding pad 120 are bonded to each other, the upper connection wire 215 may be (electrically) connected to the lower connection wire 115. Accordingly, the bit line BL and/or each of the gate electrodes 320 may be electrically connected to the peripheral circuit element 460.

FIG. 19 is an example block diagram provided to explain an electronic system according to some embodiments.

Referring to FIG. 19, an electronic system 1000 may include a semiconductor memory device 1100 described with reference to FIGS. 17 and 18, and a controller 1200 electrically connected to the semiconductor memory device 1100. The electronic system 1000 may be a storage device including one or a plurality of semiconductor memory devices 1100 or an electronic device including a storage device. For example, the electronic system 1000 may be a solid state drive device (SSD), a universal serial bus (USB), a computing system, a medical device, or a communication device, which may include one or a plurality of semiconductor memory devices 1100.

The semiconductor memory device 1100 may be, for example, the NAND flash memory device described above with reference to FIGS. 17 and 18. The semiconductor memory device 1100 may include a first structure 1100F and a second structure 1100S on the first structure 1100F. The first structure 1100F may be a peripheral circuit structure including the decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various embodiments.

In some embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one select memory cell transistor from among the plurality of memory cell transistors MCT. The decoder circuit 1110 and the page buffer 1120 may be controlled by the logic circuit 1130. The semiconductor memory device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some embodiments, the electronic system 1000 may include the plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to predetermined firmware and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written to the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. If a control command is received from the external host through the host interface 1230, in response to the control command, the processor 1210 may control the semiconductor memory device 1100. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

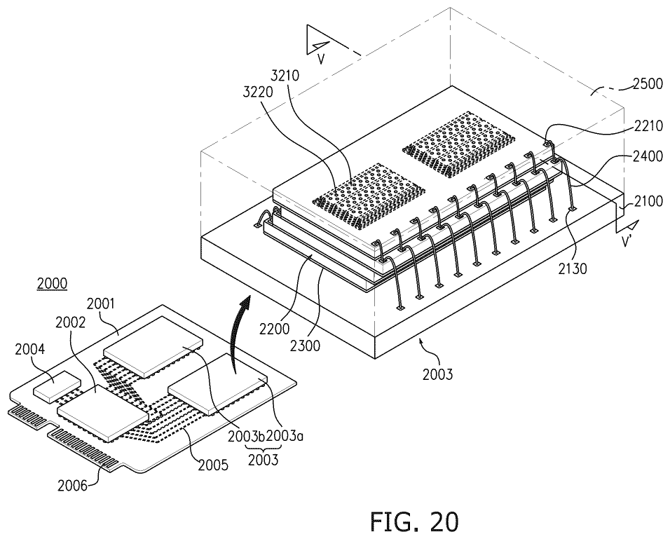

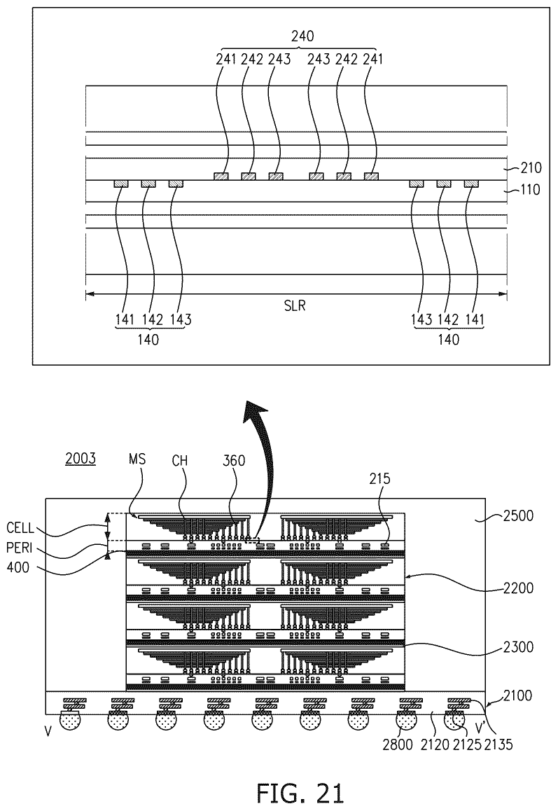

FIG. 20 is a perspective view provided as an example to explain an electronic system according to some embodiments. FIG. 21 is a schematic cross-sectional view taken along line V-V′ of FIG. 20.

Referring to FIGS. 20 and 21, an electronic system 2000 may include a main substrate 2001, a controller 2002 (also referred to as a main controller 2002) mounted on the main substrate 2001, one or more semiconductor packages 2003, and a DRAM 2004. The semiconductor package 2003 and the DRAM 2004 may be (electrically) connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host. In some embodiments, the electronic system 2000 may communicate with the external host according to any one of interfaces such as Universal Serial Bus (USB), Peripheral Component Interconnect Express (PCI-Express), Serial Advanced Technology Attachment (SATA), M-Phy for Universal Flash Storage (UFS), etc. In some embodiments, the electronic system 2000 may operate by the power supplied from the external host through the connector 2006. The electronic system 2000 may further include a power management integrated circuit (PMIC) that distributes the power supplied from the external host to the controller 2002 and the semiconductor package 2003.

The main controller 2002 may write data to the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 on (covering or overlapping) the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 19. Each of the semiconductor chips 2200 may include gate stack structures 3210 and channel structures 3220. Each of the semiconductor chips 2200 may include the semiconductor memory device described above with reference to FIGS. 17 and 18.

In some embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with a bonding wire method, and may be electrically connected to the package upper pads 2130 of the package substrate 2100. In some embodiments, in each of the first and second semiconductor packages 2003a and 2003b, the semiconductor chips 2200 may be electrically connected to each other through a connection structure including a through silicon via (TSV) instead of the bonding wire type connection structure 2400.

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be (electrically) connected to each other through wiring formed on the interposer substrate.

In some embodiments, the package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the package upper pads 2130 and the lower pads 2125 inside the package substrate body portion 2120. The package upper pads 2130 may be electrically connected to the connection structures 2400. The lower pads 2125 may be (electrically) connected to the wiring patterns 2005 of the main substrate 2001 of the electronic system 2000 through conductive connection portions 2800, as illustrated in FIG. 25.

In an electronic system according to some embodiments, each of the semiconductor chips 2200 may include the semiconductor memory device described above using FIGS. 17 and 18. For example, each of the semiconductor chips 2200 may include the peripheral circuit structure PERI and a cell structure CELL stacked on the peripheral circuit structure PERI. For example, the peripheral circuit structure PERI may include the peripheral circuit substrate 400 and a peripheral wiring 3110 described above with reference to FIGS. 17 and 18. In addition, for example, the cell structure CELL may include a common source line 3205, a gate stack structure 3210 on the common source line 3205, a channel structure 3220 and an isolation structure 3230 extending through the gate stack structure 3210, a bit line 3240 electrically connected to the channel structure 3220, and a gate connection wiring electrically connected to the word line of the gate stack structure 3210.

Each of the semiconductor chips 2200 may include a through wiring 3245 electrically connected to the peripheral wiring 3110 of the peripheral circuit structure PERI and extending into the cell structure CELL. The through wiring 3245 may be formed in (through) the gate stack structure 3210 and may be further disposed outside the gate stack structure 3210. Each of the semiconductor chips 2200 may further include an input and output connection wiring 3265 electrically connected to the peripheral wiring 3110 of the peripheral circuit structure PERI and extending into a second structure 3200, and the input and output pad 2210 electrically connected to the input and output connection wiring 3265.

Although certain embodiments of the present disclosure have been described with reference to the accompanying drawings, those of ordinary skill in the art to which the present disclosure pertains will understand that the present disclosure may be implemented in other specific forms without changing its technical idea or features. Therefore, it should be understood that the embodiments described above are illustrative and non-limiting in all respects.

1. A semiconductor device, comprising:
a substrate that comprises a first region and a second region;
a first wiring structure on the first region of the substrate, wherein the first wiring structure comprises a lower bonding pad;
a second wiring structure on the first wiring structure, wherein the second wiring structure comprises an upper bonding pad that is in contact with the lower bonding pad;
a lower alignment pattern on the second region of the substrate, wherein the lower alignment pattern is spaced apart from the lower bonding pad in a horizontal direction that is parallel with an upper surface and/or a lower surface of the substrate; and
an upper alignment pattern on the second region of the substrate, wherein the upper alignment pattern is spaced apart from the upper bonding pad in the horizontal direction,
wherein the lower alignment pattern comprises sub-lower alignment patterns,
wherein the upper alignment pattern comprises sub-upper alignment patterns,
wherein at least one of the sub-lower alignment patterns has a ring shape, and
wherein at least one of the sub-upper alignment patterns has a ring shape.

2. The semiconductor device according to claim 1, wherein an upper surface of the lower bonding pad is coplanar with an upper surface of the lower alignment pattern.

3. The semiconductor device according to claim 1, wherein a width of at least one of the sub-lower alignment patterns in a direction is 10% to 300% of a width of the lower bonding pad in the direction.

4. The semiconductor device according to claim 1, wherein a center portion of the lower alignment pattern in a plan view is at a center portion of the upper alignment pattern in the plan view.

5. A semiconductor device, comprising:
a lower interlayer insulating film;
a lower bonding pad in the lower interlayer insulating film;
a lower alignment pattern in the lower interlayer insulating film, wherein the lower alignment pattern is spaced apart from the lower bonding pad in a horizontal direction that is parallel with an upper surface and/or a lower surface of the lower interlayer insulating film;
an upper interlayer insulating film on the lower interlayer insulating film;
an upper bonding pad in the upper interlayer insulating film, wherein the upper bonding pad is in contact with the lower bonding pad; and
an upper alignment pattern in the upper interlayer insulating film, wherein the upper alignment pattern is spaced apart from the upper bonding pad in the horizontal direction,
wherein the lower alignment pattern comprises sub-lower alignment patterns, and
wherein a width of at least one of the sub-lower alignment patterns in a direction is 10% to 300% of a width of the lower bonding pad in the direction.

6. The semiconductor device according to claim 5, wherein the upper alignment pattern comprises sub-upper alignment patterns, and
wherein a width of at least one of the sub-upper alignment patterns in the direction is 10% to 300% of a width of the upper bonding pad in the direction.

7. The semiconductor device according to claim 5, wherein each of the sub-lower alignment patterns is spaced apart from each other at regular intervals.

8. The semiconductor device according to claim 5, wherein the lower alignment pattern comprises a first sub-lower alignment pattern and a second sub-lower alignment pattern adjacent to the first sub-lower alignment pattern, and
wherein a distance by which the first sub-lower alignment pattern and the second sub-lower alignment pattern are spaced apart from each other is less than a width of the first sub-lower alignment pattern.

9. The semiconductor device according to claim 5, wherein each of the lower alignment pattern and the upper alignment pattern has a circular or quadrangular shape.

10. The semiconductor device according to claim 5, wherein the width of the lower bonding pad in the direction is equal to a width of the upper bonding pad in the direction.

11. The semiconductor device according to claim 5, wherein the lower interlayer insulating film comprises a first surface and a second surface that is opposite to the first surface in a vertical direction that is perpendicular to the upper surface and/or the lower surface of the lower interlayer insulating film,
wherein the lower bonding pad and the lower alignment pattern are on the first surface of the lower interlayer insulating film, and
wherein the upper interlayer insulating film comprises a third surface on which the upper bonding pad and the upper alignment pattern are positioned and a fourth surface that is opposite to the third surface in the vertical direction.

12. The semiconductor device according to claim 11, wherein the first surface of the lower interlayer insulating film and the third surface of the upper interlayer insulating film are in contact with each other.

13. The semiconductor device according to claim 5, further comprising:
a first semiconductor chip below the lower interlayer insulating film, wherein the first semiconductor chip is electrically connected to the lower bonding pad; and
a second semiconductor chip above the upper interlayer insulating film, wherein the second semiconductor chip is electrically connected to the upper bonding pad.

14. The semiconductor device according to claim 5, wherein a shape of the lower alignment pattern and a shape of the upper alignment pattern are same as each other, and
wherein a cross-sectional area of the lower alignment pattern is greater than a cross-sectional area of the upper alignment pattern.

15. The semiconductor device according to claim 5, wherein the upper alignment pattern is in the lower alignment pattern in a plan view.

16. The semiconductor device according to claim 5, wherein the lower interlayer insulating film comprises a first insulating layer and a first bonding layer on the first insulating layer, and
wherein the upper interlayer insulating film comprises a second bonding layer on the first bonding layer and a second insulating layer on the second bonding layer.

17. The semiconductor device according to claim 16, further comprising:
a bonding oxide film between the first bonding layer and the second bonding layer.

18. The semiconductor device according to claim 5, wherein at least one of the sub-lower alignment patterns has a linear shape.

19. A semiconductor device, comprising:
a substrate that comprises a first region and a second region that is adjacent the first region;
a peripheral circuit structure on the first region;
a cell structure on the peripheral circuit structure; and
a lower alignment pattern and an upper alignment pattern on the second region of the substrate, wherein the cell structure comprises:
gate electrodes that are stacked on and spaced apart from each other in a first direction that is perpendicular to an upper surface and/or a lower surface of the substrate;
a channel structure that extends into the gate electrodes in the first direction;
a bit line that is electrically connected to the channel structure; and
an upper bonding pad that is electrically connected to the bit line,
the peripheral circuit structure comprises:
a lower bonding pad that is in contact with the upper bonding pad; and
a peripheral circuit element that is electrically connected to the lower bonding pad,
wherein the lower alignment pattern comprises sub-lower alignment patterns,
wherein a width of at least one of the sub-lower alignment patterns in a second direction is 10% to 300% of a width of the lower bonding pad in the second direction, and
wherein the second direction is parallel with the upper surface and/or the lower surface of the substrate.

20. The semiconductor device according to claim 19, wherein the upper alignment pattern comprises sub-upper alignment patterns, and
wherein a width of at least one of the sub-upper alignment patterns in the second direction is 10% to 300% of a width of the upper bonding pad in the second direction.
